(19) United States
(12) Patent Application Publication
(10) Pub. No.: US 2017/0052298 A1
(43) Pub. Date: Feb. 23, 2017

(54) SYSTEMS FOR AND METHODS OF AMBIENT-LIGHT REDUCTION IN OLED DISPLAY SYSTEMS AND LCD SYSTEMS

(71) Applicant: Corning Incorporated, Corning, NY (US)

(72) Inventors: Jaymin Amin, Corning, NY (US); Raymond Geroe Greene, Ithaca, NY (US); Tomohiro Ishikawa, Corning, NY (US); Jum Sik Kim, Horseheads, NY (US); Cheng-Chung Li, Painted Post, NY (US); Michal Mlejnek, Big Flats, NY (US); Tina Marie Proulx, Addison, NY (US)

(73) Assignee: Corning Incorporated, Corning, NY (US)

(21) Appl. No.: 15/118,633

(22) PCT Filed: Feb. 12, 2015
(86) PCT No.: PCT/US15/15573

§ 371 Date: Aug. 12, 2016

Related U.S. Application Data
(60) Provisional application No. 61/939,982, filed on Feb. 14, 2014.

(51) Int. Cl. G02B 5/23; H01L 51/52; G02F 1/1335; H01L 27/32; G02B 1/11; G02B 5/20

(52) U.S. Cl. CPC G02B 5/23; G02B 1/11; G02B 5/205; G02F 1/133509; H01L 27/3232; H01L 51/5281; G02F 2001/133562; G02F 2202/14

(57) ABSTRACT

Systems and methods for ambient-light reduction in display systems with OLED or LCD based displays are disclosed. The base display is interfaced with an ambient-light-reducing (ALR) structure to form the display system. The ALR structure includes an ALR component. The ALR component can be a photochromic component or a fixed neutral-density component. The ALR structure attenuates incoming ambient light as well as outgoing redirected ambient light that is generated within the base display and is then emitted from the display system into the ambient environment. This increases the ambient contrast relative to that of the base display alone.

This application claims the benefit of priority to U.S. Application No. 61/939,982 filed on Feb. 14, 2014 the content of which is incorporated herein by reference it its entirety.

### FIELD

The present disclosure relates to displays, particularly to organic light-emitting diode (OLED) display system and liquid-crystal display (LCD) systems, and more particularly to systems for and methods of ambient-light reduction for such display systems.

### BACKGROUND

OLED displays and LCDs are used in a variety of devices such as computers, television screens, smartphones, tablet computers and the like. OLED displays utilize organic LED panels that generate light from an organic semiconductor layer disposed between two electrodes and so do not require a backlight. LCDs utilize liquid-crystal panels to modulate light from a backlight or from a reflective surface.

OLED displays and LCDs are each made up of a number of different layers. For example, an OLED display includes an array of OLEDs formed from the aforementioned organic semiconductor layer and the two electrodes (i.e., an anode and a cathode) and a support substrate. Likewise, a typical LCD includes a polarized film, a glass substrate with transparent electrodes, an LC layer, a glass substrate with a transparent conducting electrode, another polarized layer, and a reflective surface or backlight surface. These layered structures tend to both specularly and diffusely redirect ambient light that enters the display from the ambient environment. A portion of the redirected ambient light exits the display and is seen by a person viewing the display. This reduces the display contrast and thus the readability of the display.

One conventional means for reducing the adverse viewing effects of ambient light is to use an antireflection (AR) coating on the outermost display layer or cover sheet. While this is useful for reducing the specular reflection component from the display, it is not as effective at reducing the redirected component that arises from the various layers within the display. In fact, an AR coating tends to amplify the diffuse redirected component because it increases the amount of ambient light that enters the display and that gets redirected. The redirected ambient light can become particularly problematic in bright environments, especially outdoors.

### SUMMARY

Systems and methods for ambient-light reduction in OLED displays and LCDs are disclosed. A base display is interfaced with an ambient-light-reducing (ALR) structure to form a display system. The ALR structure includes at least one ALR component. The ALR component can be a photochromic component or a fixed neutral-density component. The ALR structure attenuates incoming ambient light as well as outgoing redirected ambient light generated within the base display and emitted from the display system and into the ambient environment. This increases the ambient contrast relative to that of the base display alone.

An aspect of the disclosure is a display system that displays a display image in either a low-light or a bright-light ambient environment. The system includes: a base display configured to generate the display image, the base display including either an OLED display or a LCD and having an upper surface and structures that form redirected ambient light from ambient light incident thereon; an ALR structure interfaced with the upper surface of the base display and having an upper surface and a photochromic component, wherein the ambient light travels through the photochromic component toward the base display and interacts with the structures to form the redirected ambient light, which travels through the photochromic component and out of the upper surface of the ALR structure; the photochromic component having a transparent mode in the low-light ambient environment wherein the photochromic component does not substantially attenuate either the ambient light or the redirected ambient light that passes therethrough; and the photochromic component having a darkened mode in the bright-light ambient environment wherein the photochromic component substantially attenuates the ambient light and the redirected ambient light that passes therethrough.

Another aspect of the disclosure is a display system that displays a display image in either a low-light or a bright-light ambient environment. The system includes: a base display configured to generate the display image, the base display including an OLED display and having upper surface structures that form redirected ambient light from ambient light incident thereon; an ALR structure interfaced with the upper surface of the base display and having an upper surface and a neutral-density component, wherein the ambient light travels through the neutral-density component toward the base display and interacts with the structures to form the redirected ambient light, which travels through the neutral-density component and out of the upper surface of the ALR structure; and wherein the neutral-density component has a fixed transmission T in the range 30%≦T≦85% for visible wavelengths.

Another aspect of the disclosure is a method of reducing an amount of redirected ambient light emitted by a display system that has an upper surface and includes a base display that has an upper surface and structures that form the redirected ambient light from ambient light. The method includes: arranging adjacent the upper surface of the base display a photochromic component having a transparent mode when in a low-light ambient environment with low ambient light and a darkened mode when in a bright-light ambient environment with bright ambient light; when in the low-light environment and the transparent mode, transmitting the low ambient light through the photochromic component to the structures to form the redirected ambient light, and passing a first amount of the redirected ambient light through the photochromic component and out of the display upper surface; and when in the bright-light environment and the darkened mode, transmitting the bright ambient light through the photochromic component to the structures to form the redirected ambient light, and passing the redirected ambient light through the photochromic component to create a second amount of redirected ambient light that is emitted from the display upper surface, wherein the second amount of attenuated redirected ambient light is less than the first amount.

Another aspect of the disclosure is a method of reducing an amount of redirected ambient light emitted from an OLED base display that has an upper surface and structures that form the redirected ambient light from ambient light. The method includes: arranging adjacent the upper surface of the base display a neutral-density component having a fixed transmission T in the range 30%≦T≦85%, a thickness TH1 in the range 0.5 mm≦TH1≦5 mm, and an upper surface that interfaces directly with the ambient environment; transmitting the ambient light through the neutral-density component to the structures to form the redirected ambient light; and passing the diffusely redirected ambient light through the neutral-density component and out of the upper surface and into the ambient environment.

Additional features and advantages are set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary and are intended to provide an overview or framework to understand the nature and character of the claims.

### BRIEF DESCRIPTION OF THE DRAWINGS

The accompanying drawings are included to provide a further understanding and are incorporated in and constitute a part of this specification. The drawings illustrate one or more embodiment(s) and together with the Detailed Description serve to explain principles and operation of the various embodiments. As such, the disclosure will become more fully understood from the following Detailed Description, taken in conjunction with the accompanying Figures, in which:

FIG. 1 is a front-on view of an example display device that includes the display system according to the disclosure, wherein the display device and its display image is shown in the form of a smartphone by way of example;

FIG. 2 is a cross-sectional view of an example display device according to the disclosure, wherein the display device includes an OLED or LCD base display and an ALR structure interfaced with the base display having at least one ALR component;

FIG. 3 is a cross-sectional view of an example display device similar to FIG. 2, wherein the ALR component includes a chemically strengthened photochromic cover sheet;

FIG. 4A is the example display device of FIG. 3 shown in a low-light environment, illustrating how ambient light enters the display device and forms redirected ambient light that is seen by a user viewing the display image;

FIG. 4B is similar to FIG. 4A, but with the display device in a bright-light environment that causes the chemically strengthened photochromic cover sheet to darken, which serves to reduce the amount of redirected ambient light that would reach the user as compared to the amount had the cover sheet remained transparent;

FIG. 5 is similar to FIG. 4B and illustrates an example embodiment of the display system wherein the ALR component of the ALR structure includes a neutral-density layer;

FIGS. 6A and 6B are similar to FIGS. 4A and 4B and illustrate an example embodiment of the display system wherein the ALR component of the ALR structure includes a photochromic adhesive layer; and

FIGS. 7A and 7B are similar to FIGS. 6A and 6B and illustrate an example embodiment of the display system wherein the ALR component of the ALR structure includes a photochromic layer.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute a part of this Detailed Description.

The entire disclosure of any publication or patent document mentioned herein is incorporated by reference.

Cartesian coordinates are shown in some of the Figures for the sake of reference and are not intended to be limiting as to direction or orientation.

The term “ambient contrast” is used herein is a measure of the readability of a display in daylight and is described, for example, in the article by Kelley et al., “Display daylight ambient contrast measurement methods and daylight readability,” J. Soc. Information Display 14, no. 11 (November 2006): 1019-1030.

The ambient contrast ratio (ACR) is defined as BB/BD, where BB is the brightness of the display when showing a bright image and BD is the brightness of the display when showing a dark image. The ACR is measured in the presence of a select amount of ambient illumination on the display.

The term “photochromic component” refers to a component that has a first mode (or “transparent” mode) in a low-light ambient environment, wherein the component is substantially transparent, and a second mode (or “darkened” mode) in a bright-light ambient environment, wherein the component has substantial attenuation as compared to the transparent mode. The transition between the first and second modes is caused by a substantial amount of activating light being present in the bright-light environment. In an example, the activating light has a non-visible (e.g., ultraviolet) wavelength. The transition between the first mode and the second mode can be continuous and depends on the amount of activating light that passes through the photochromic component. Some activating light may be present in the low-light environment but not in sufficient amounts to initiate a substantial change in transmission of the photochromic component from the first to the second mode. The transmission in the first or “transparent” mode is denoted T1 and the transmission in the second or “darkened” mode is denoted T2.

The term “transmission” as used herein in connection with the ambient-light-reducing (ALR) component introduced below refers to the bulk optical transmission of the component, i.e., it does not include transmission losses due to surface reflections. The transmission of the ALR component can be determined from the absorbance per unit length a multiplied by the thickness of the ALR component.

### Display Device

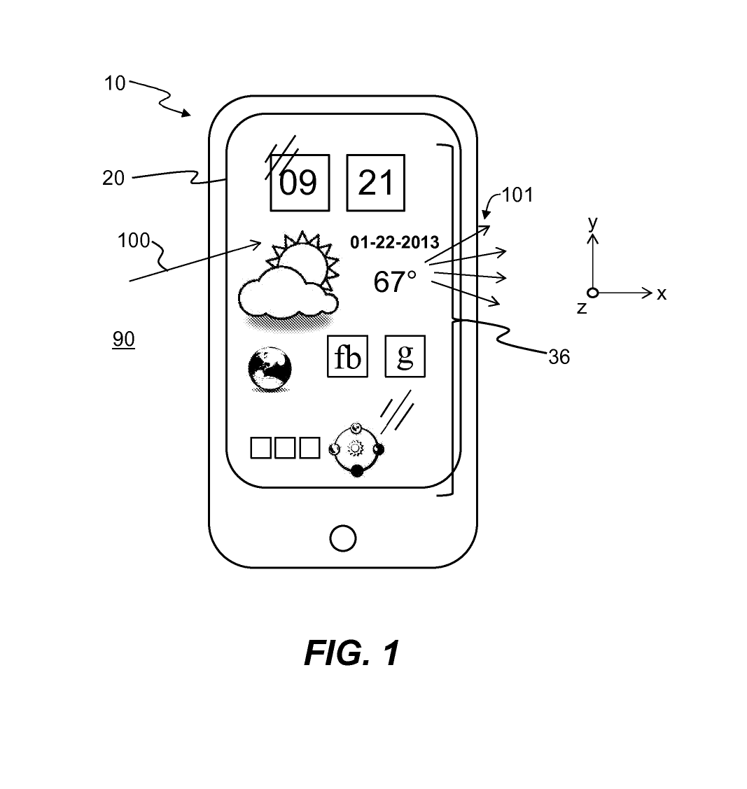

FIG. 1 is a front-on view of an example display device 10 shown in the form of a smartphone by way of example. The display device 10 can be any one of a number of different types of display devices that might be used in low-light and bright-light environments. Example display devices include smartphones, cell phones, tablets, electronic readers, laptop computers, televisions, etc. The display device 10 includes a display system 20 according to the disclosure and as described in greater detail below. The display device 10 resides in an ambient environment 90 that includes ambient light 100 that can be incident upon and enter display system 20. The ambient light 100 that enters display system 20 (i.e., incoming light) can give rise to redirected ambient light 101 that is emitted from the upper surface of the display system as outgoing light that reduces the ambient contrast.

### Display System

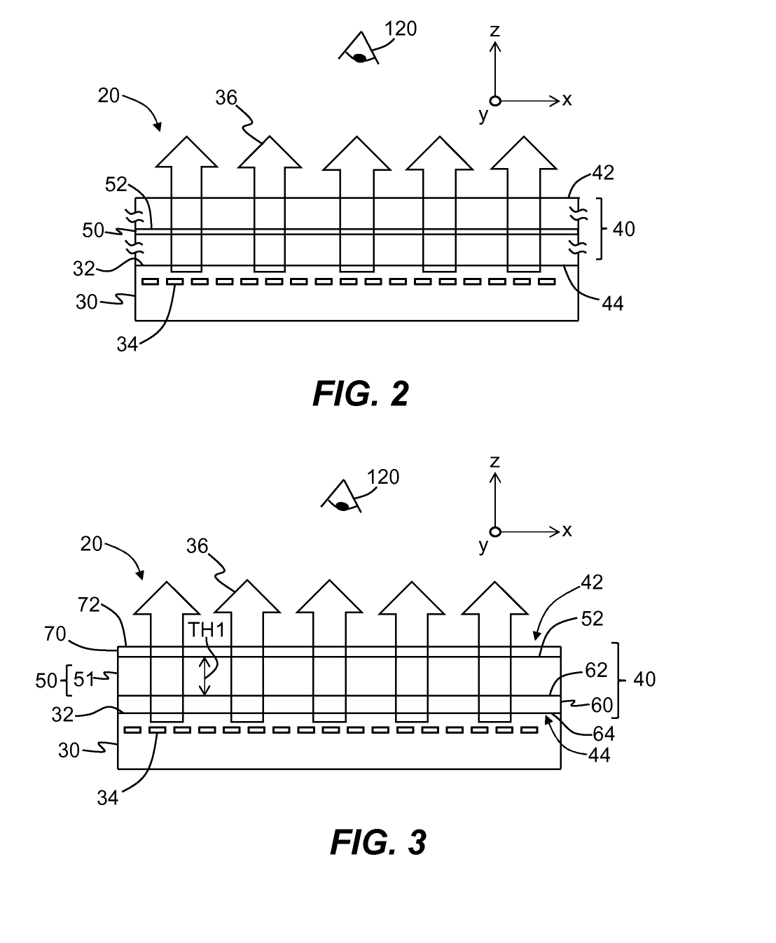

FIG. 2 is a cross-sectional view of display system 20 according to the disclosure, as taken in the x-z plane. The display system 20 includes a base display 30. The base display 30 can be OLED-based or LCD-based. The base display 30 includes an upper surface 32 and one or more structures 34 that diffusely redirect ambient light 100 that enters display system 20 from ambient environment 90 and is incident thereon. The structures 34 may diffusely and specularly reflect ambient light 100 incident thereon. In an example, structures 34 are defined by refractive index differences between different layers of base display 30 so that the redirected ambient light 101 can originate at different depths within the base display.

The base display 30 emits display light 36 that is viewed by a viewer (user) 120 and that represents a corresponding display image formed by the base display. Thus, display light 36 is also referred to as “display image” 36. An example display image 36 is shown on display system 20 in FIG. 1.

The display system 20 also includes an ambient-light-reducing (ALR) structure 40 that has an upper surface 42 that defines the upper surface of the display system and a lower surface 44 that interfaces with upper surface 32 of base display 30. The upper surface 42 typically represents the outermost surface of display system 20, i.e., the surface that interfaces with ambient environment 90 (thus, upper surface 42 is also the upper surface of the display system). Thus, display image 36 is viewed by viewer 120 through ALR structure 40.

The function of ALR structure 40 is to substantially reduce the amount of redirected ambient light 101 that is emitted from upper surface 42 of display system 20 as compared to the amount of redirected ambient light emitted by base display 30 when the ALR structure is not present. In an example, this function is accomplished while also maintaining a sufficiently high ACR, e.g., ACR>10 or ACR>50 or even ACR>100. In an example, the ACR of display system 20 with ALR structure 40 is greater than the ACR of base display 30.

The ALR structure 40 includes at least one ALR component 50 that has an upper surface 52. In one example, ALR component 50 includes a photochromic component having the aforementioned transparent and darkened modes, depending on whether it is in a low-light or bright-light environment. In another example, ALR component 50 has a non-changing (fixed) neutral-density that defines a select attenuation per unit length a, which in turn defines a select (fixed) transmission T for a given thickness TH1. Example display systems 20 that utilize ALR structure 40 with different types of ALR components 50 are described in greater detail below.

Example materials for ALR component 50 include a glass or a polymer. An example thickness range for thickness TH1 is 0.05 mm≦TH1≦5 mm. In the case of a photochromic ARL component 50 that is polymer-based, an example range on the absorbance a is 0.2 cm⁻¹≦α≦100 cm⁻¹. In the case of a photochromic ARL component 50 that is glass-based, an example range on the absorbance a is 0.2 cm⁻¹≦α≦10 cm⁻¹.

Display System with Chemically Strengthened Photochromic Cover Sheet

FIG. 3 is similar to FIG. 2 and shows a cross-sectional view of an example display system 20. The ALR structure 40 includes a substantially transparent adhesive layer 60 that resides atop upper surface 32 and that includes an upper surface 62 and a lower surface 64. Example materials for transparent adhesive layer 60 include silicone resin and optically cross-linked polymer. In an example, adhesive layer 60 serves to attach (interface) ALR structure 40 to base display 30.

The ALR structure 40 also includes an antireflection (AR) coating 70 having an upper surface 72 that defines upper surface 42. The ALR component 50 is sandwiched between transparent adhesive layer 60 and AR coating 70.

The ALR component 50 of ALR structure 40 includes a chemically strengthened photochromic cover sheet 51 that resides atop upper surface 62 of transparent adhesive layer 60. In an example, ALR component 50 consists of a single photochromic cover sheet 51 of thickness TH1, as shown in FIG. 3. In an example, the thickness of photochromic cover sheet 51 is in the range 0.5 mm≦TH1≦5 mm. In an example, photochromic cover sheet 51 is made of chemically strengthened glass. An example of such a glass is Gorilla® glass (available from Corning, Inc., of Corning, N.Y.), which incorporates a photochromic material, such as silver halide, within the glass matrix. In another example, photochromic cover sheet 51 is made of a material other than glass, e.g., plastic, polymer, acrylic, etc., that includes one or more types of photochromic organic molecules know in the art, e.g., triarylmethanes, stilbenes, azastilbenes, nitrones, fulgides, spiropyrans, naphthopyrans, spiro-oxazines, quinones, etc.

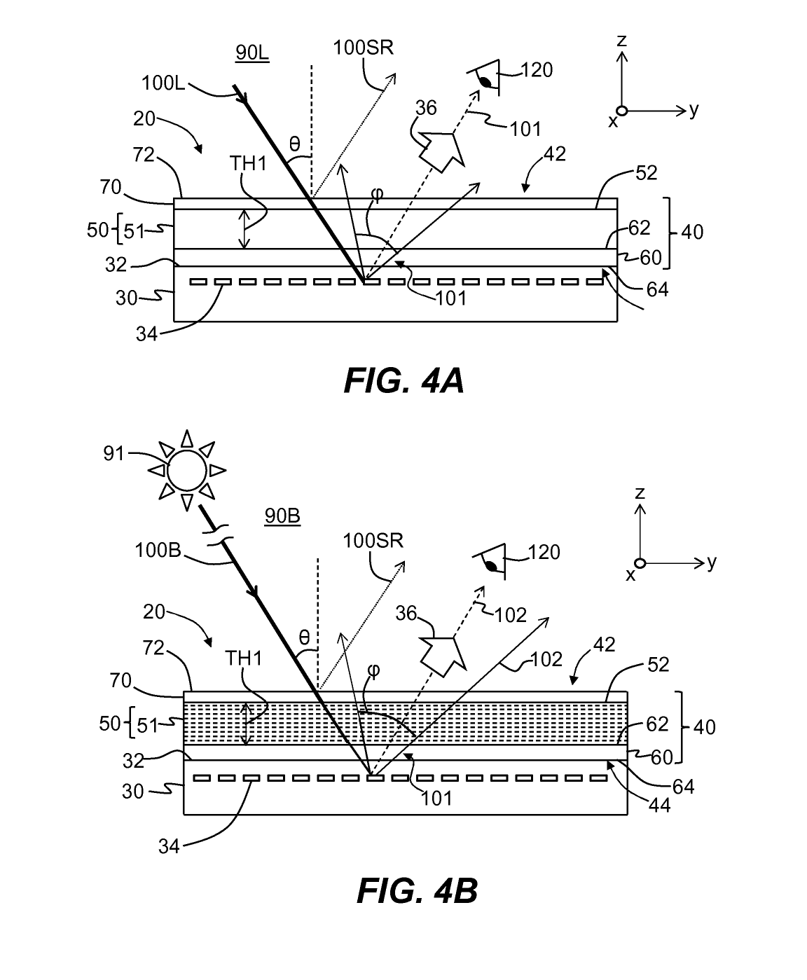

FIG. 4A is similar to FIG. 3 and illustrates how display system 20 behaves in a low-light environment 90L. For ease of illustration, display image 36 is shown as a single large arrow, and refraction effects within display system 20 are ignored. Dim (i.e., low-intensity) ambient light 100L from low-light environment 90L is shown incident upon upper surface 72 of AR coating 70 at an incident angle θ relative to the z-direction. In low-light environment 90L, photochromic cover sheet 51 is in the transparent mode, i.e., has a transmission T1 (e.g., 80% or greater) so that it is substantially transparent in the low-light environment. The AR coating 70 reduces the amount of specularly reflected light 100SR (dotted line). The specular reflection of ambient light at normal incidence in the presence of an AR coating 70 is typically less than 4%. This means that more of dim ambient light 100L will enter display system 20.

A portion of dim ambient light 100L that enters display system 20 will be redirected over an angular range φ by structures 34 of base display 30 to form redirected ambient light 101. The angular range φ defines where most of the redirected ambient light 101 travels. Some redirected ambient light 101 can reside outside of the angular range φ. In an example, redirected ambient light 101 includes diffusely reflected light and specularly reflected light. The redirected ambient light 101 can also include scattered light.

A portion of redirected ambient light 101 (dashed-line arrow) travels through transparent adhesive layer 60, photochromic cover sheet 51 and AR coating 70 and is emitted from upper surface 42 of display system 20 and reaches viewer 120, who is trying to view display image 36. The behavior of display system 20 in low-light environment 90L up to this point is the same as that of a conventional display system that utilizes a clear cover sheet.

FIG. 4B is similar to FIG. 4A, but with display system 20 in a bright-light environment 90B that includes bright ambient light 100B. In the example shown in FIG. 4B, bright-light environment 90B is a daylight environment, and bright ambient light 100B is daylight, e.g., direct or indirect sunlight from sun 91. As in the case of low-light environment 90L, AR coating 70 decreases the amount of reflection of bright ambient light 100B from upper surface 52 of photochromic cover sheet 51 so that more of the bright ambient light enters display system 20.

The non-visible (e.g., ultraviolet) activating component of bright ambient light 100B triggers the photochromic effect in photochromic cover sheet 51, thereby causing the photochromic cover sheet to transition from the transparent mode to the darkened mode, which has a reduced transmission T2 (i.e., T2<T1) over the visible spectrum. This reduced transmission T2 gives the photochromic cover sheet a gray color, which is indicative of a neutral-density (i.e., generally uniform) attenuation of wavelengths in the visible spectrum.

The attenuation of bright ambient light 100B as it travels through photochromic cover sheet 51 reduces the amount of bright ambient light that reaches the internal structures 34 of base display 30 as compared to the amount had the photochromic cover sheet remained in the transparent mode (or if it were absent). A portion of bright ambient light 100B that reaches the internal structures 34 of base display 30 is redirected over the aforementioned angular range φ to form the aforementioned redirected ambient light 101.

The redirected ambient light 101 is attenuated as it travels back through photochromic cover sheet 51, thereby forming attenuated redirected ambient light 102. The attenuated redirected ambient light 102 passes through AR coating 70, and a portion of this light is seen by viewer 120, who is viewing display image 36.

Thus, bright ambient light 100B undergoes two attenuations by passing twice through (darkened-mode) photochromic cover sheet 51 when display system 20 is in bright-light environment 90B, but undergoes substantially no attenuation (or substantially less attenuation) when passing twice through the (transparent-mode) photochromic cover sheet when the display system is in low-light environment 90L. Thus, the amount of redirected ambient light 101 emitted from display system 20 in the transparent mode is greater than the amount emitted in the darkened mode.

It is noted here that AR coating 70 is usually not an effective AR barrier for light traveling through the AR coating from within ALR structure 40 since the AR coating is designed to perform its function with an air interface on upper surface 72.

The use of photochromic cover sheet 51 enables the ambient contrast of display system 20 to be dynamically controlled. This allows for improved readability of base display 30 in bright-light environment 90B while also maintaining the conventional readability in the low-light (e.g., indoor or night-time) environment 90L.

The improved readability of display system 20 in bright-light environment 90B has the advantage of not having to rely only on increasing the intensity of the light-emitting elements or light source of base display 30 to increase the brightness of display image 36. This feature conserves energy and in the case where batteries are used to power base display 30, serves to extend the operating time for a given battery charge.

In an example of display system 20, photochromic cover sheet 51 has a transmission T1 of 80%≦T1<100% in the visible spectrum in low-light environment 90L and a transmission T2 of 30%≦T2≦85% in the visible spectrum in bright-light environment 90B, with the additional condition that T2<T1.

Display System with a Neutral-Density Layer

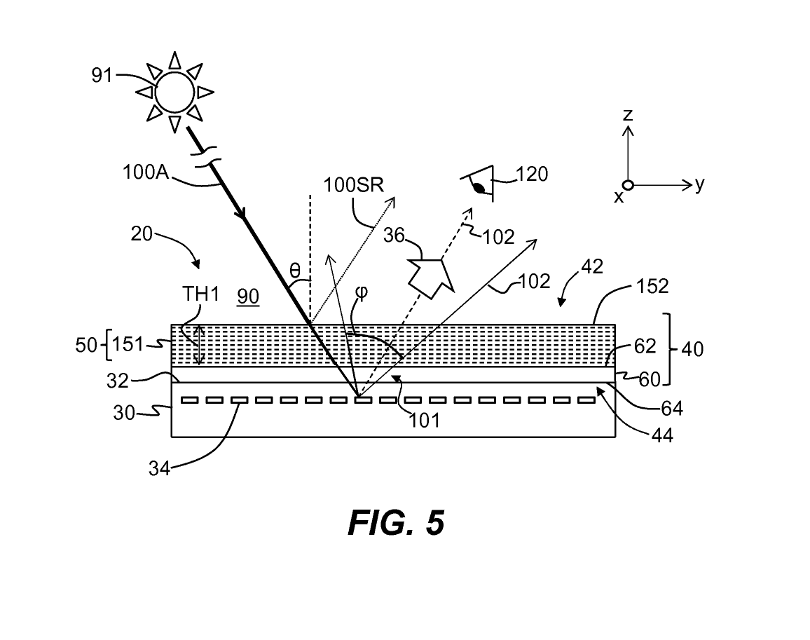

FIG. 5 is similar to FIG. 4B and illustrates an example embodiment of display system 20 wherein ALR component 50 includes a neutral-density layer 151 having an upper surface 152 that defines the uppermost surface of ALR structure 40 and thus display system 20. In an example, ALR component 50 consists of a single neutral-density layer 151 of thickness TH1, which in an example is in the range 0.5 mm≦TH1≦5 mm, and has a fixed transmission T in the range 30%≦T≦85%. In an example, neutral-density layer 151 is in the form of a sheet of neutral-density material. In an example, neutral-density layer 151 serves as a cover sheet for display system 20. The AR coating 70 (not shown) is optional.

In an example, the single neutral-density layer 151 is made of a sheet of neutral-density glass, polymer, acrylic, plastic, etc. In an example, neutral-density layer 151 consists of or otherwise includes a chemically strengthened glass, such as the aforementioned Gorilla® glass. The neutral density of neutral-density layer 151 means that visible wavelengths are attenuated substantially in equal amounts. The base display 30 in the embodiment of display system 20 of FIG. 5 is OLED-based. OLED-based displays are known for having a relatively high diffuse reflectivity of ambient light 100.

FIG. 5 shows ambient light 100A incident upon display system 20 from an ambient environment 90, which can be a low-light, bright-light or intermediate-light environment. A portion of ambient light 100A specularly reflects from upper surface 152 of neutral-density layer 151 as specularly reflected light 100SR (dotted line) while most of the ambient light is transmitted through the upper surface. The transmitted ambient light 100A is attenuated as it travels through neutral-density layer 151. The attenuated transmitted ambient light 100A then travels through transparent adhesive layer 60, and a portion of this light is redirected by structures 34 of OLED-based base display 30 to form redirected ambient light 101 having an angular range φ. The redirected ambient light 101 then travels through transparent adhesive layer 60 and through neutral-density layer 151 to viewer 120, who is viewing display image 36.

Thus, ambient light 100A undergoes two attenuations by passing twice through neutral-density layer 151, regardless of the brightness of ambient environment 90. This double attenuation can be exploited to improve the ACR. Table 1 below sets forth the ACRs as measured with 600-lux ambient light 100A for a conventional OLED display with an AR coating, for a conventional OLED display without an AR coating, and for an example OLED-based display system 20 with neutral-density layer 151 (in the form of neutral-density glass) without an AR coating.

TABLE 1

| DEVICE | ACR |
|---|---|
| Conventional OLED display | 430 |
| with AR coating | |
| Conventional OLED display | 554 |
| without AR coating | |
| OLED display system with 80% | 618 |
| neutral gray neutral-density glass | |
| and no AR coating | |

Table 1 indicates that the OLED-based display system 20 that utilizes neutral-density layer 151 with 80% neutral density and no AR coating 70 has a higher ARC than do the conventional OLED displays, either with or without an AR coating.

It is noted here that it is widely understood that an AR coating on the upper surface of a display serves to increase the ambient contrast ration of the display. However, the inventors have discovered that in certain cases the AR coating can actually serve to decrease the ambient contrast ratio. One such case is for an OLED base display 30, which has structures 34 that give rise substantial amounts of redirected light 101 with a large diffuse component as compared to the specular component. The AR coating increases the amount of ambient light 100 that reaches structures 34, thereby giving rise to an increase amount of redirected light 101 that reaches viewer 120.

Display System with Photochromic Adhesive Layer

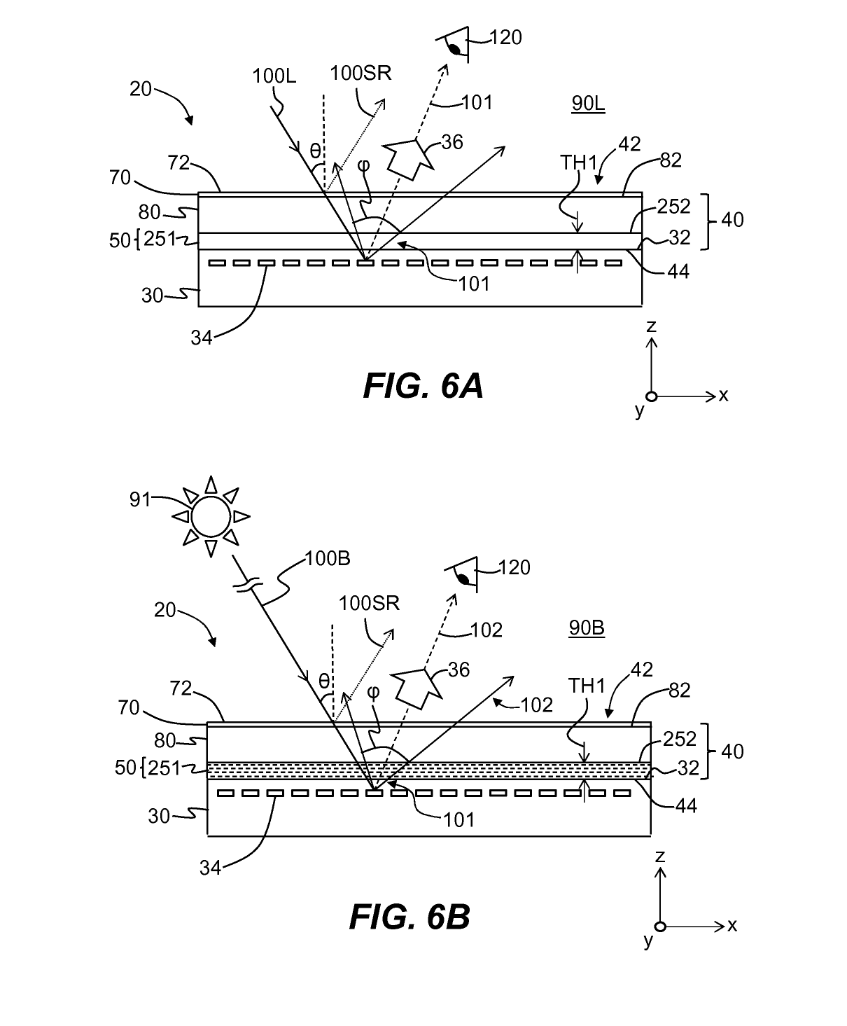

FIG. 6A is similar to FIG. 4A and illustrates an example display system 20 wherein ALR structure 40 includes a clear (i.e., optically transparent) cover sheet 80 with an upper surface 82 upon which resides AR coating 70. The ALR component 50 includes a photochromic adhesive layer 251 having an upper surface 252 upon which transparent cover sheet 80 resides. In an example, ALR component 50 consists of a single photochromic adhesive layer 251 that replaces transparent adhesive layer 60, as shown.

In an example, photochromic adhesive layer 251 is formed by mixing a photochromic dye with an optically clear (transparent) adhesive. UV cross-linking can be used for solidification (e.g., UV curing) once transparent cover sheet 80 is interfaced with photochromic adhesive layer 251.

In an example embodiment, photochromic adhesive layer 251 becomes polarized upon darkening when irradiated by an activating wavelength that is outside of the visible wavelength spectrum, e.g., that is a UV-wavelength. In other words, photochromic adhesive layer 251 also has a polarized mode that occurs with the darkened mode. In this case, the direction of polarization of polarized photochromic adhesive layer 251 is made to substantially align with the polarization direction of the underlying base display 30 to provide maximum transmission of display light 36 by avoiding an adverse cross-polarizer effect.

In FIG. 6A, dim (i.e., low-intensity) ambient light 100L from low-light environment 90L is shown incident upon upper surface 72 of AR coating 70 at an incident angle θ relative to the z-direction. The AR coating 70 reduces the specular reflection, shown as specularly reflected light 100SR (i.e., the dotted line), which means that more of dim ambient light 100L will enter display system 20. A portion of the transmitted dim ambient light 100L travels through transparent cover sheet 80 and photochromic adhesive layer 251, which is in the transparent mode because of the relatively low intensity of ambient light 100L or because of the lack of activating ultraviolet light (e.g., from non-UV-generating indoor lighting).

The ambient light 100L is then incident upon structures 34 of base display 30 and is redirected by the structures to form redirected ambient light 101. A portion of redirected ambient light 101 (i.e., the dashed-line arrow) travels through photochromic adhesive layer 251, transparent cover sheet 80 and AR coating 70 to user 120, who is viewing display image 36. The behavior of display system 20 in low-light environment 90L is thus the same as that of a conventional display that utilizes a clear cover sheet.

In the example shown in FIG. 6B, display system 20 is in bright-light ambient environment 90B that includes bright ambient light 100B. The AR coating 70 decreases the amount of reflection of bright ambient light 100B from display upper surface 42 so that more of the bright ambient light enters display system 20 and travels through transparent cover sheet 80 to photochromic adhesive layer 251.

The non-visible (e.g., ultraviolet) active wavelength of bright ambient light 100B triggers the photochromic effect in photochromic adhesive layer 251, thereby causing the photochromic adhesive layer to transition to the darkened mode, which has a reduced transmission T2 (i.e., T2<T1) over the visible spectrum. This reduced transmission T2 gives the photochromic adhesive layer 251 a gray color, which is indicative of neutral-density (i.e., generally uniform) attenuation of wavelengths in the visible spectrum. The attenuation of bright ambient light 100B within photochromic adhesive layer 251 reduces the amount of bright ambient light that reaches structures 34 of base display 30. The portion of bright ambient light 100B that reaches structures 34 of base display 30 is redirected over the aforementioned angular range φ to form redirected ambient light 101.

The redirected ambient light 101 is attenuated as it travels back through (darkened) photochromic adhesive layer 251, thereby forming attenuated redirected ambient light 102. The attenuated redirected ambient light 102 passes through AR coating 70 and a portion of this light reaches viewer 120.

In the case where photochromic adhesive layer 251 becomes polarized upon darkening, additional attenuation of bright ambient light 100B occurs during the first pass of the bright ambient light through the polarized photochromic adhesive layer. This assumes that bright ambient light 100B is initially randomly polarized, which is true of most bright-light ambient environments 90B, especially outdoor environments. Randomly polarized light that passes through a perfect polarizer is attenuated by a factor of 0.5. The precise amount of attenuation of bright ambient light 100B by polarized photochromic adhesive layer 251 depends on the actual degree of the polarization (e.g., as measured by the extinction coefficient produced by crossing two such polarized layers) and on the layer thickness TH1.

In an example of display system 20, photochromic adhesive layer 251 has a transmission T1 in the transparent mode of 80%≦T1<100% in the visible spectrum in low-light environment 90L and a transmission T2 in the darkened mode of 30%≦T2≦85% in the visible spectrum in bright-light environment 90B, with the condition that T2<T1. In an example, photochromic adhesive layer 251 has a thickness TH1 in the range 0.05 mm≦TH1≦5 mm.

Thus, bright ambient light 100B undergoes two attenuations by passing twice through photochromic adhesive layer 251 (and an optional attenuation of up to 0.5 if the layer is also polarized in the darkened mode) when display system 20 is in bright-light environment 90B, but undergoes substantially no attenuation when the display system is in low-light environment 90L.

The use of photochromic adhesive layer 251 in ALR structure 40 enables the dynamic control of the ambient contrast of display system 20. This allows for improved readability of base display 30 in bright-light environment 90B while also maintaining the conventional readability in low-light (e.g., indoor or night-time) environment 90L. The improved readability in bright-light environment 90B has the advantage of not having to rely only on increasing the intensity of the light-emitting elements or light source of base display 30. This feature conserves energy, and in the case where batteries are used to power base display 30, serves to extend the operating time for a given battery charge.

Display System with Photochromic Layer

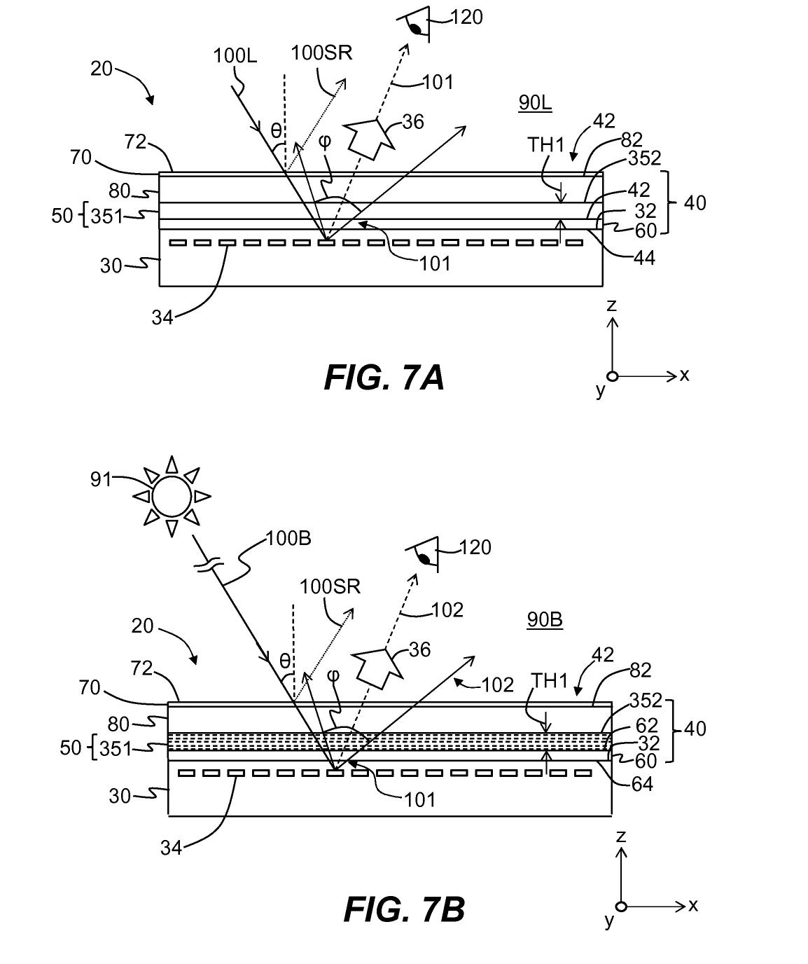

FIG. 7A is similar to FIG. 6A and illustrates an example display system 20 wherein ALR structure 40 includes ALR component 50 sandwiched between transparent cover sheet 80 and transparent adhesive layer 60, with AR coating 70 atop upper surface 82 of the transparent cover sheet.

The ALR component 50 includes a photochromic layer 351 with an upper surface 352. In an example, ALR component 50 consists of a single photochromic layer 351. The photochromic layer 351 can be formed by coating a glass substrate with a monomer mixture of organic photochromic dyes, followed by curing, e.g., via thermal or UV exposure.

In an example embodiment, photochromic layer 351 becomes polarized upon darkening by the irradiation of the layer with an activating wavelength that is outside of the visible wavelength, e.g., that is a UV-wavelength. In other words, photochromic layer 351 also has a polarized mode that occurs with the darkened mode. In this case, the direction of polarization of photochromic layer 351 is made to substantially align with that of the underlying base display 30 to provide maximum transmission of display light 36 by avoiding an adverse cross-polarizer effect.

In FIG. 7A, dim (i.e., low-intensity) ambient light 100L from low-light environment 90L is shown incident upon upper surface 72 of (optional) AR coating 70 at an incident angle θ relative to the z-direction. The AR coating 70 reduces the specular reflection, which is shown as specularly reflected light 100SR (i.e., the dotted line), which means that more of the dim ambient light 100L will enter display system 20. A portion of the transmitted dim ambient light 100L travels through transparent cover sheet 80 and through photochromic layer 351, which has a transmission T1 that is substantially transparent because of the relatively low intensity of ambient light 100L or because of the lack of activating ultraviolet light (e.g., from non-UV-generating indoor lighting).

The dim ambient light 100L then passes through transparent adhesive layer 60 and is then incident upon structures 34 of base display 30 and diffusely reflects therefrom to form redirected ambient light 101. A portion of redirected ambient light 101 (i.e., the dashed-line arrow) travels through transparent adhesive layer 60, through photochromic layer 351, through transparent cover sheet 80 and AR coating 70 and is seen by viewer 120, who is viewing display image 36. The behavior of display system 20 in low-light environment 90L is thus the same as that of a conventional display.

In the example shown in FIG. 7B, display system 20 is in bright-light environment 90B, which includes bright ambient light 100B. The AR coating 70 decreases the amount of reflection of bright ambient light 100B from upper surface 42 of ALR structure 40 so that more of the bright ambient light enters transparent cover sheet 80 and travels to photochromic layer 351.

The non-visible (e.g., ultraviolet) component of bright ambient light 100B triggers the photochromic effect in photochromic layer 351, thereby causing the photochromic layer to transition to the darkened mode, which has a reduced transmission T2 (i.e., T2<T1) over the visible spectrum. This reduced transmission gives photochromic layer 351 a gray color, which is indicative of neutral-density (i.e., generally uniform) attenuation of wavelengths in the visible spectrum. The attenuation of bright ambient light 100B within photochromic layer 351 due to the reduced transmission T2 reduces the amount of bright ambient light that reaches structures 34 of base display 30. The portion of bright ambient light 100B that reaches structures 34 of base display 30 is redirected over the aforementioned angular range φ to form redirected ambient light 101.

The redirected ambient light 101 is attenuated as it travels back through transparent adhesive layer 60 and through photochromic layer 351, thereby forming attenuated redirected ambient light 102. The attenuated redirected ambient light 102 passes through transparent cover sheet 80 and AR coating 70, and a portion of this light is seen by viewer 120.

In the case where photochromic layer 351 becomes polarized upon darkening, additional attenuation of bright ambient light 100B occurs during the first pass of the bright ambient light through the polarized photochromic layer. This assumes that bright ambient light 100B is initially randomly polarized, which is true of most bright-light ambient environments 90B, especially outdoor environments. As noted above, randomly polarized light that passes through a perfect polarizer is attenuated by a factor of ½. The precise amount of attenuation of bright ambient light 100B by polarized photochromic layer 351 depends on the actual strength of the polarization (e.g., as measured by the extinction coefficient produced by crossing two such polarized layers) and on the layer thickness TH1.

In an example of display system 20, photochromic layer 351 has a transmission T1 in the transparent mode of 80%≦T1<100% in the visible spectrum in low-light environment 90L and a transmission T2 in the darkened mode of 30%≦T2≦85% in the visible spectrum in bright-light environment 90B, with the condition that T2<T1. In an example, photochromic layer 351 has a thickness TH1 in the range 0.05 mm≦TH1≦5 mm.

Thus, bright ambient light 100B undergoes two attenuations by passing twice through photochromic layer 351 (and an optional attenuation of up to 0.5 if the layer is polarized) when display system 20 is in bright-light environment 90B, but undergoes substantially no attenuation when the display system is in low-light environment 90L.

The use of photochromic layer 351 in ALR structure 40 enables the dynamic control of the amount of attenuated redirected ambient light 102 reaching user 120 to improve the ambient contrast of display system 20. This allows for improved readability of display image 36 of base display 30 in bright-light environment 90B while also maintaining the conventional readability in low-light (e.g., indoor or night-time) environment 90L. The improved readability in bright-light environment 90B has the advantage of not having to rely only on increasing the intensity of the light-emitting elements or light source of base display 30. This feature conserves energy and in the case where batteries are used to power base display 30, serves to extend the operating time for a given battery charge.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

1. A display system that displays a display image in either a low-light or a bright-light ambient environment, the display system comprising:
a base display configured to generate the display image, the base display including at least one of an organic light-emitting diode (OLED) display or a liquid crystal display (LCD), the base display having an upper surface and structures that form redirected ambient light from ambient light incident thereon;
an ambient-light-reducing (ALR) structure interfaced with the upper surface of the base display and having an upper surface, and a photochromic component, and an antireflection coating, wherein the ambient light travels through the photochromic component toward the base display and interacts with the structures to form the redirected ambient light, which travels through the photochromic component and out of the upper surface of the ALR structure;
the photochromic component having a transparent mode in the low-light ambient environment wherein the photochromic component does not substantially attenuate either the ambient light or the redirected ambient light that passes therethrough; and
the photochromic component having a darkened mode in the bright-light ambient environment wherein the photochromic component substantially attenuates the ambient light and the redirected ambient light that passes therethrough.

2. The display system according to claim 1, wherein the photochromic component has a transmission T1 in the transparent mode of 80%≦T1≦100% and a transmission T2 in the darkened mode of 30%≦T2≦85%, and where T2<T1.

3. The display system according to claim 1, wherein the darkened mode includes a polarization mode wherein the photochromic component is polarized.

4. The display system according to claim 1, wherein the photochromic component comprises a photochromic cover sheet.

5. The display system according to claim 4, wherein the photochromic cover sheet consists of a single sheet of chemically strengthened photochromic glass.

6. The display system according to claim 1, wherein the ALR structure includes a transparent adhesive layer and the antireflection coating that sandwich the photochromic component, and wherein the transparent adhesive layer attaches the ALR structure to the upper surface of the base display.

7. The display system according to claim 1, wherein the photochromic component includes a photochromic adhesive layer that attaches the ALR structure to the upper surface of the base display.

8. The display system according to claim 7, wherein the ALR structure includes a transparent cover sheet atop the photochromic adhesive layer, and the antireflection coating atop the transparent cover sheet.

9. The display system according to claim 1, wherein the ALR structure includes a transparent adhesive and a transparent cover sheet, and wherein the photochromic component includes a photochromic layer sandwiched by the transparent adhesive layer and the transparent cover sheet.

10. The display system according to claim 9, wherein the ALR structure further includes the antireflection coating atop the transparent cover sheet.

11. A display system that displays a display image in either a low-light or a bright-light ambient environment, the display system comprising:
a base display configured to generate the display image, the base display including an organic light-emitting diode (OLED) display, the base display having an upper surface and structures that form redirected ambient light from ambient light incident thereon;
an ambient-light-reducing (ALR) structure interfaced with the upper surface of the base display and having an upper surface and a neutral-density component, wherein the ambient light travels through the neutral-density component toward the base display and interacts with the structures to form the redirected ambient light, which travels through the neutral-density component and out of the upper surface of the ALR structure; and
wherein the neutral-density component has a fixed transmission T in the range 30%≦T≦85% for visible wavelengths.

12. The display system according to claim 11, wherein the neutral-density component consists of a single neutral-density glass sheet having a thickness TH1 in the range 0.5 mm≦TH1≦5 mm.

13. The display system according to claim 12, wherein the neutral-density glass sheet is made of a chemically strengthened glass.

14. The display system according to claim 12, wherein the ALR structure consists of:
the single neutral-density glass sheet having an upper surface and a lower surface; and
a transparent adhesive layer residing between the lower surface of the neutral-density glass sheet and upper surface of the base display.

15. A method of reducing an amount of redirected ambient light emitted by a display system that has an upper surface and that includes a base display that has an upper surface and structures that form the redirected ambient light from ambient light, the method comprising:
arranging adjacent the upper surface of the base display a photochromic component and an antireflection coating, the photochromic component having a transparent mode when in a low-light environment with low ambient light and a darkened mode when in a bright-light environment with bright ambient light;
when in the low-light environment and the transparent mode, transmitting the low ambient light through the photochromic component and the antireflection coating to the structures to form the redirected ambient light, and passing a first amount of the redirected ambient light through the photochromic component and the antireflection coating and out of the display upper surface; and
when in the bright-light environment and the darkened mode, transmitting the bright ambient light through the photochromic component and the antireflection coating to the structures to form the redirected ambient light, and passing the redirected ambient light through the photochromic component and the antireflection coating to create a second amount of redirected ambient light that is emitted from the display upper surface, wherein the second amount of redirected ambient light is less than the first amount of redirected ambient light.

16. The method according to claim 15, wherein the photochromic component comprises a photochromic cover sheet.

17. The method according to claim 15, wherein the photochromic component comprises a photochromic adhesive that secures a transparent cover sheet to the base display.

18. The method according to claim 15, wherein the photochromic component comprises a photochromic layer arranged between a transparent adhesive layer and a transparent cover sheet.

19. The method according to claim 15, wherein the photochromic component has a transmission T1 in the transparent mode of 80%≦T1<100% and a transmission T2 in the darkened mode of 30%≦T2≦85%, wherein T2<T1.

20. The method according to claim 15, wherein the darkened mode includes a polarization mode wherein the photochromic component is polarized.

21-22. (canceled)
